(19) United States
(12) Patent Application Publication
(10) Pub. No.: US 2026/0074487 A1
(43) Pub. Date: Mar. 12, 2026

(54) VERTICAL CAVITY SURFACE EMITTING LASER AND METHOD FOR PRODUCING SAME

(71) Applicant: TRUMPF Photonic Components GmbH, Ulm (DE)

(72) Inventors: Roman Koerner, Lonsee (DE); Daniela Stange, Langenau (DE)

(21) Appl. No.: 19/393,608

(22) Filed: Nov. 19, 2025

Related U.S. Application Data
(63) Continuation of application No. PCT/EP2024/061963, filed on Apr. 30, 2024.

(30) Foreign Application Priority Data
May 24, 2023 (DE) 10 2023 113 538.4

(51) Int. Cl. H01S 5/183; H01S 5/30; H01S 5/343

(52) U.S. Cl. CPC H01S 5/18361; H01S 5/3095; H01S 5/343

(57) ABSTRACT

A vertical-cavity surface-emitting laser includes a first reflector connected to a first semiconductor substrate, a second reflector, and an active region including a quantum well structure for emitting light. The active region is located in series between the first reflector and the second reflector. The first reflector is located in series between the first semiconductor substrate and the active region. A surface of an outer face of the first semiconductor substrate that faces away from the first reflector has an orientation mark that is configured so as to define a position of the vertical-cavity surface-emitting laser in a plane in parallel with the outer face of the first semiconductor substrate.

### CROSS REFERENCE TO RELATED APPLICATIONS

This application is a continuation of International Application No. PCT/EP2024/061963 (WO 2024/240455 A1), filed on Apr. 30, 2024, and claims benefit to German Patent Application No. DE 10 2023 113 538.4, filed on May 24, 2023. The aforementioned applications are hereby incorporated by reference herein.

### FIELD

Embodiments of the present invention relate to a vertical-cavity surface-emitting laser, and to a method for producing such a vertical-cavity surface-emitting laser.

### BACKGROUND

Vertical-cavity surface-emitting lasers (VCSELs), also known as surface-emitting semiconductor lasers, are a type of semiconductor laser diode whose laser beam is emitted perpendicular to the top or bottom of the device. A VCSEL typically comprises two distributed Bragg reflectors (DBR) arranged parallel to the wafer surface and an active region arranged between the Bragg reflectors having one or a plurality of quantum wells for generating the laser light. Bragg reflectors typically comprise layers with alternating high and low refractive indices.

To produce VCSELs, the Bragg reflectors and the active region arranged between them can be produced separately and then joined together by wafer bonding (fusion bonding). Document U.S. Pat. No. 6,542,531 B2 describes such a method for producing a VCSEL, in which, in a first step, the active region with quantum wells and a tunnel junction is grown on a semiconductor substrate and then structured by etching. Separate from the active region, two Bragg reflectors are fabricated by epitaxially growing the different layers on another semiconductor substrate and are each connected to one side of the active region by wafer bonding. Finally, the substrate of the upper DBR is removed by etching and electrical contacts are applied to the component.

The production of a modern VCSEL requires complex method steps. For example, adapting different materials for the reflectors and the active region requires several structuring steps before, during and after wafer bonding. A challenge in the production of VCSELs is that, for the VCSEL to subsequently function correctly, the production steps require precise alignment of the layers and their structuring.

To ensure this, markings are often applied during the production method, by means of which the correct orientation can be verified. Various techniques for marking and verifying the orientation have become established in the prior art. In a variant in which the active region with quantum wells and tunnel junction layer and the two Bragg reflectors are produced separately and connected by wafer bonding, the marking is applied by structuring the tunnel junction layer. In order for the marking to remain visible in the assembled VCSEL, one of the Bragg mirrors in the area of the marking must be removed in this variant, which requires an additional work step.

In an alternative variant, in which the marking is also located in the tunnel junction layer, the marking is determined by means of infrared radiation through the component. With this variant, no material needs to be removed in order to detect the marking. However, due to the wavelength of the infrared radiation, the accuracy of detecting the marking is limited, so that this variant is not suitable for many applications due to the insufficient resolution.

In further variants, the markings are transferred from a first marking to one of the new layers after the deposition of several layers. With this variant, the additional method step of subsequent material removal can also be omitted. However, transferring the markings requires additional effort. A further disadvantage of these variants is that inaccuracies can occur each time a marking is transferred, which may be exacerbated if it is transferred multiple times. These variants are therefore also not suitable for many applications due to the insufficient alignment accuracy.

### SUMMARY

Embodiments of the present invention provide a vertical-cavity surface-emitting laser. The vertical-cavity surface-emitting laser includes a first reflector connected to a first semiconductor substrate, a second reflector, and an active region including a quantum well structure for emitting light. The active region is located in series between the first reflector and the second reflector. The first reflector is located in series between the first semiconductor substrate and the active region. A surface of an outer face of the first semiconductor substrate that faces away from the first reflector has an orientation mark that is configured so as to define a position of the vertical-cavity surface-emitting laser in a plane in parallel with the outer face of the first semiconductor substrate.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a first embodiment of a VCSEL; and

FIG. 2 shows a second embodiment of a VCSEL.

### DETAILED DESCRIPTION

Embodiments of the invention can improve the known production methods for VCSELs in such a way that a precise alignment of the resulting component during execution of the individual method steps is ensured in a simple manner.

In the following, in the absence of any indication to the contrary, any reference to one (including by means of indefinite and definite articles), two or any other number of items shall be understood such that the presence of additional such items is not excluded. The reference symbols in all claims have no limiting effect and are intended solely to improve their readability.

The terms “before”, “after”, “between” and “on” used below may refer to a relative position of a layer with respect to other layers. A layer that lies “on top of” or is bonded “to” another layer may be in direct contact with the other layer or may have one or a plurality of intermediate layers. A layer “between” layers may be in direct contact with the layers or have one or a plurality of intermediate layers.

The vertical-cavity surface-emitting laser according to embodiments of the invention comprises a first reflector, which is connected to a first semiconductor substrate, a second reflector, and an active region having a quantum well structure for emitting light, which active region is located in series between the first reflector and the second reflector, wherein the first reflector is located in series between the first semiconductor substrate and the active region, wherein the surface of the outer face of the first semiconductor substrate, which surface faces away from the first reflector, has an orientation mark that is designed so as to clearly define the position of the vertical-cavity surface-emitting laser in a plane in parallel with the outer face of the first semiconductor substrate.

The method according to embodiments of the invention for producing a vertical-cavity surface-emitting laser having a first semiconductor substrate, a first reflector, a second reflector and an active region with a quantum well structure for generating light, which is arranged in series between the first reflector and the second reflector, comprises the steps:
a) providing the first semiconductor substrate, on which the first reflector is produced;
b) providing a second semiconductor substrate, on which the second reflector is produced;
c) providing a third semiconductor substrate and epitaxial growth of the active region with the quantum well structure on the third semiconductor substrate;
d) connecting the first reflector to the active region;
e) removing the third semiconductor substrate;
f) connecting the second reflector to the active region; and
g) removing the second semiconductor substrate;
   wherein, prior to the execution of step f), on the surface of the outer face of the first semiconductor substrate facing away from the first reflector, an orientation mark that is designed so as to clearly define the position of the vertical-cavity surface-emitting laser in a plane in parallel with the outer face of the first semiconductor substrate is produced.

The VCSEL according to embodiments of the invention and the method for its production according to embodiments of the invention have the advantage that a precise alignment of all steps of the production method is possible due to the orientation mark on the outer face of the semiconductor substrate, which is not altered during the production method. A further advantage over the prior art, in which markings are applied in the active region, is that the active region does not have to be altered in the method according to embodiments of the invention. This enables a significantly more flexible design of the active region and a simpler production of the same compared to the prior art.

The VCSEL according to embodiments of the invention comprises two reflectors. The first reflector and the second reflector are part of an optical resonator, by means of which the light generated in the quantum well structure is amplified before it leaves the VCSEL.

Preferably, the first reflector and the second reflector are multi-layer reflectors, each constructed from a plurality of layers of different materials. Particularly preferably, the first reflector and the second reflector are designed as Bragg reflectors (distributed Bragg reflectors, DBR), also referred to as Bragg mirrors. Bragg reflectors are typically formed from a plurality of pairs of layers consisting of a material system that generally consists of two materials with different refractive indices and can be easily adapted to the other parts of the VCSEL. Preferred material systems for DBRs are undoped layers of aluminum arsenide (AlAs) and gallium arsenide (GaAs), of aluminum gallium arsenide (AlGaAs) and AlAs, or of AlGaAs and GaAs. The different refractive indices of the individual layers of a pair can be achieved by changing the aluminum content in the layers.

For the production of the VCSEL according to embodiments of the invention, the method steps a) and b) can comprise both the provision of reflectors already prefabricated on semiconductor substrates and the production of reflectors on semiconductor substrates. The reflectors can be produced in different ways. Corresponding methods are known from the prior art. Preferably, the reflectors are produced on a semiconductor substrate, in particular a wafer, to which they are firmly connected. Preferably, the first semiconductor substrate and/or the second semiconductor substrate is a GaAs wafer.

The active region, which is arranged between the two reflectors in the completed state of the VCSEL, comprises at least one quantum well structure for emitting light. Corresponding structures are known in the prior art, for example as so-called heterostructures. According to embodiments of the invention, the active region is produced by epitaxial growth on a third semiconductor substrate. The material of the third semiconductor substrate is preferably indium phosphide (InP). Preferably, the third semiconductor substrate is a wafer, in particular an InP wafer. Additional layers having the lattice constant of InP can advantageously be grown on the InP wafer, for example an InP buffer layer, InGaAsP bonding layers, InAlAs intermediate layers or InAlGaAs/InP quantum wells.

In one embodiment, the vertical-cavity surface-emitting laser further comprises a tunnel junction region arranged in series between the first reflector and the second reflector. The tunnel junction region is also called the “tunnel contact”.

Preferably, the tunnel junction region comprises two highly doped semiconductor layers
of different conductivity types (e.g. n++-doped and p++-doped). Preferably, the tunnel junction region comprises n++-doped indium gallium aluminum arsenide (InGaAlAs) and p++-doped InGaAlAs.

In one embodiment, a buffer region is arranged between the quantum well structure and the tunnel junction region, which can also be epitaxially grown. Preferably, the buffer region is formed from an undoped semiconductor material, in particular from undoped InP.

To produce this embodiment, preferably in step c) a tunnel junction region is further produced in series before or after the quantum well structure in the active region by means of epitaxial growth. If a buffer region is intended, this is also preferably produced in step c) by means of epitaxial growth.

The VCSEL according to embodiments of the invention may also comprise multiple layers of quantum wells, a plurality of layers of tunnel junction regions and/or a plurality of layers of buffer regions. To produce such designs, preferably in step c) of the production method, a plurality of quantum well structures for generating light, a plurality of tunnel junction regions and/or a plurality of buffer regions are epitaxially grown in series.

In a preferred embodiment, the active region comprises a plurality of quantum well structures for generating light and a plurality of tunnel junction regions which are arranged alternately in series between the first reflector and the second reflector. Such an arrangement has the advantage that a significantly higher light output of the laser can be achieved despite its compact design.

To produce this embodiment, preferably in step c) of the production method, a plurality of quantum well structures for generating light and a plurality of tunnel junction regions are epitaxially grown alternately in series. This has the advantage that the active region can be produced in a simple and efficient manner. A further advantage is that, by growing all layers consecutively on the substrate, inaccuracies in the alignment of structures at the transitions between layers, which can occur in some known production methods, are avoided.

This design is made possible by the fact that the orientation feature is applied to the outer face of the first semiconductor substrate. In state-of-the-art devices, in which the markers in the active region are produced by structuring a layer, an arrangement of a plurality of active centers is not possible with sufficient accuracy. The reasons for this are that (i) structuring steps that produce a topography within the VCSEL region require the quantum well structure to be grown on the topography, which would drastically reduce its quality, and (ii) structuring steps that locally alter the conductivity would, due to the high temperatures required in the subsequent overgrowth, affect the structured profile, leading to significant errors in the orientation accuracy.

In one embodiment, the vertical-cavity surface-emitting laser further comprises a first current distribution layer and a first contact and a second current distribution layer and a second contact for exciting the VCSEL with electrical current. The types, shapes and positions of the current distribution layers and contacts can be selected according to the respective requirements of the VCSEL, for example with regard to its intended use.

In one embodiment, the vertical-cavity surface-emitting laser comprises a first current distribution layer and a first contact, wherein the first contact is in electrical connection with the first current distribution layer and the first current distribution layer is arranged between the first reflector and the active region, and a second current distribution layer and a second contact, wherein the second contact is in electrical connection with the second current distribution layer and the second current distribution layer is arranged between the second reflector and the active region.

In this embodiment, the first current distribution layer and the second current distribution layer are preferably etch stop layers. Etch stop layers are usually applied at specific locations during the layer-by-layer production of a VCSEL in order to limit the effect of etching to specific layers in the subsequent production method, in which structuring is carried out by etching. The use of etch stop layers as current distribution layers has the advantage that no additional effort is required to produce the current distribution.

To produce an embodiment with current distribution layers, the first current distribution layer and the second current distribution layer are preferably epitaxially grown at the corresponding location in step c). Preferably, in step c), a current distribution layer is epitaxially grown both before the growth of a quantum well structure and/or a tunnel junction region and after the growth of all quantum well structures and/or tunnel junction regions.

To produce a VCSEL according to embodiments of the invention, three separate components are connected to each other: the first reflector to the active region and the second reflector to the active region. The respective connections according to steps d) and f) of the method according to embodiments of the invention are preferably made by wafer bonding (fusion bonding).

The surfaces to be joined can be pretreated before joining if required. In one embodiment, one or both surfaces to be joined are cleaned. In a further embodiment, before step d), the surface of the first reflector is structured, in particular by nanoimprinting, lithography, etching, local diffusion and/or local defect generation.

Since the active region was grown on the third semiconductor substrate, it is necessary to remove the substrate before the active region can be connected to the second reflector. Removal is preferably done by etching. For this purpose, an etch stop layer is advantageously applied as a first layer between the third semiconductor substrate and the active region.

After the second reflector has been connected to the active region, the second semiconductor substrate is removed in step g) of the method according to embodiments of the invention. Removal is preferably done by etching. In one variant, an etch stop layer is applied between the second semiconductor substrate and the second reflector. In another variant, the material of the second semiconductor substrate is selectively removable, so that no etch stop layer is required.

According to embodiments of the invention, the surface of the outer face of the first semiconductor substrate facing away from the first reflector has an orientation mark. The orientation mark is produced before executing step f). The orientation mark may have any shape suitable for uniquely defining the position of the vertical-cavity surface-emitting laser in a plane in parallel to the outer face of the first semiconductor substrate. An unambiguous definition in a plane is given, for example, when two identifiable parts of the marking have different spatial coordinates in the plane.

The orientation mark may be a single mark with at least two identifiable parts or may consist of a plurality of components. In one embodiment, the orientation mark comprises two separate partial marks that are applied at different locations on the surface of the outer face of the first semiconductor substrate facing away from the first reflector. Particularly preferably, the two partial markings are applied at locations on the surface that are as far apart as possible, in particular on opposite sides of the surface. In the case of a circular cross-section of the surface, the two partial markings are preferably placed at the outer points of a line through the center of the circle.

The orientation mark may also contain more than two identifiable parts, in particular partial markings, for example three, four or five.

The size of the orientation mark or its parts is preferably selected such that it can be detected with sufficient precision using the available apparatuses and detection techniques. The orientation marks can be precisely produced, for example, by etching or laser engraving.

The orientation mark can be created at any time in the production method as long as the marking is not required for a subsequent method step. For example, the orientation mark may already be present on the first semiconductor substrate on which the first reflector is produced during the provision according to step a). Preferably, the orientation mark is already produced after step a) by introducing it into the provided first semiconductor substrate.

The method steps of the production method according to embodiments of the invention do not necessarily have to be carried out in the specified sequence unless a mandatory order results from logic. For example, steps a) to c) of the production method can be carried out in any order or simultaneously.

In the following description of preferred embodiments of the present invention, like reference numerals designate like or comparable components. If there are several identical components, usually only one is provided with a reference symbol.

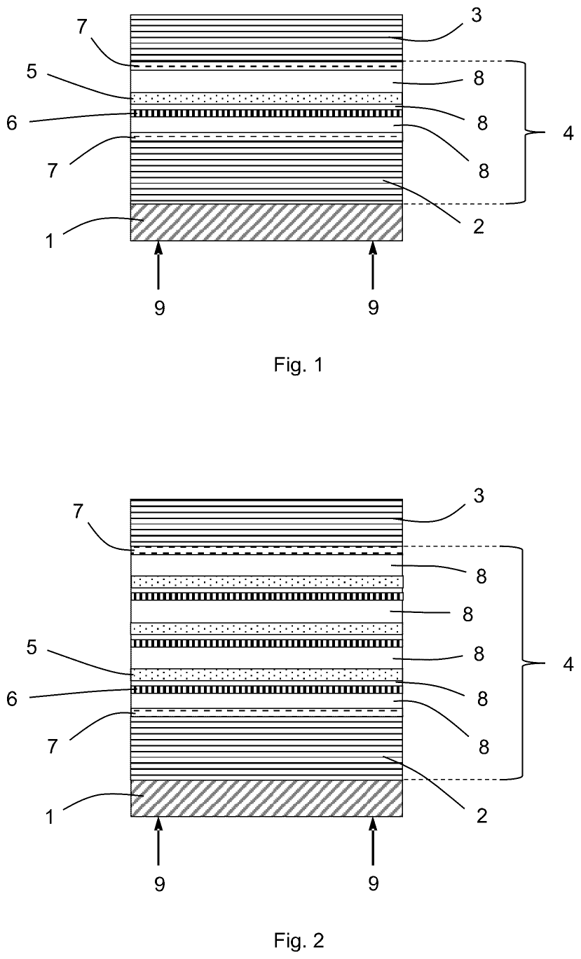

FIG. 1 schematically shows a first embodiment of a VCSEL according to embodiments of the invention. The VCSEL shown in FIG. 1 can be produced using the method shown below.

A DBR as the first reflector 2 with alternating layers of GaAs and AlGaAs is epitaxially grown on a GaAs wafer as the first semiconductor substrate 1. The surface of the first semiconductor substrate 1 facing away from the DBR is provided with an orientation mark 9 comprising two partial marks arranged on opposite sides of the surface (indicated by the two arrows in FIG. 1). The orientation mark 9 can be produced, for example, by etching or laser engraving. The orientation mark 9 enables precise orientation for all subsequent method steps.

On a further GaAs wafer serving as the second semiconductor substrate, an etch stop layer 7 of AlGaAs and, subsequently, a DBR as a second reflector 3 with alternating layers of GaAs and AlGaAs are epitaxially grown. As an alternative to GaAs, Ge can be used as a material for the second semiconductor substrate. Since Ge can be selectively removed later in the process, no etch stop layer is required between the DBR and the substrate when Ge is used as the substrate material. The use of Ge has the further advantage that defect-free mirror growth is possible, which results in an increase in bonding quality.

The following layers are epitaxially grown on an InP wafer as the third semiconductor substrate in the specified order: an etch stop layer 7 made of InGaAsP, an InP layer as buffer layer 8, an active region 4 with quantum wells 5, another InP layer as buffer layer 8, a tunnel junction layer (6), another InP layer as buffer layer 8 and another etch stop layer 7.

The third semiconductor substrate, including the layers grown on it, is placed on the DBR of the first semiconductor substrate and connected to it by wafer bonding. The connected component has the GaAs layer of the first semiconductor substrate 1 on one side and the InP layer of the third semiconductor substrate on the other side. The latter is then removed by etching down to the etch stop layer 7. The surface exposed by etching is cleaned and then structured, for example by photolithography followed by etching. In the case of the production of a plurality of quantum films, it is advisable to implant or diffuse another material instead of etching in order to electrically define the tunnel junction regions.

After structuring is complete, the surface is cleaned again. The DBR applied to the second semiconductor substrate is then placed with its surface onto the cleaned structured surface and connected by wafer bonding. In the final step, the second semiconductor substrate is removed. Due to the orientation mark 9 on the underside of the VCSEL, it can be precisely positioned in further method steps.

FIG. 2 schematically shows a second embodiment of a VCSEL according to embodiments of the invention. This differs from the first embodiment described above with reference to FIG. 1 only in that the active region 4 has a plurality of sequentially successive quantum well structures 5 and tunnel junction regions 6. To produce the VCSEL shown in FIG. 2, the same method can be used as described above with respect to the first embodiment. During the production of the active region 4, the plurality of quantum well structures 5 for generating light and the plurality of tunnel junction regions 6 are epitaxially grown alternately in series.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SYMBOLS

1 First semiconductor substrate
2 First reflector
3 Second reflector
4 Active region
5 Quantum well structure
6 Tunnel junction region
7 Etch stop layer
8 Buffer layer
9 Orientation mark

1. A vertical-cavity surface-emitting laser comprising:
a first reflector connected to a first semiconductor substrate,
a second reflector, and
an active region comprising a quantum well structure for emitting light, wherein the active region is located in series between the first reflector and the second reflector, wherein the first reflector is located in series between the first semiconductor substrate and the active region,
wherein a surface of an outer face of the first semiconductor substrate that faces away from the first reflector has an orientation mark that is configured so as to define a position of the vertical-cavity surface-emitting laser in a plane in parallel with the outer face of the first semiconductor substrate.

2. The vertical-cavity surface-emitting laser according to claim 1, further comprising a tunnel junction region arranged in series between the first reflector and the second reflector.

3. The vertical-cavity surface-emitting laser according to claim 1, wherein the active region comprises a plurality of quantum well structures including the quantum well structure for generating light and a plurality of tunnel junction regions, wherein the plurality of quantum well structures and the plurality tunnel junctions are arranged alternately in series between the first reflector and the second reflector.

4. The vertical-cavity surface-emitting laser according to claim 1, further comprising:
a first current distribution layer and a first contact, wherein the first contact is in electrical connection with the first current distribution layer, and the first current distribution layer is arranged between the first reflector and the active region, and
a second current distribution layer and a second contact, wherein the second contact is in electrical connection with the second current distribution layer, and the second current distribution layer is arranged between the second reflector and the active region.

5. The vertical-cavity surface-emitting laser according to claim 4, wherein the first current distribution layer and the second current distribution layer are etch stop layers.

6. A method for producing a vertical-cavity surface-emitting laser, the vertical-cavity surface-emitting laser comprising a first semiconductor substrate, a first reflector, a second reflector and an active region with a quantum well structure for generating light, wherein the active region is arranged in series between the first reflector and the second reflector, the method comprising:
a) providing the first semiconductor substrate, on which the first reflector is produced;
b) providing a second semiconductor substrate, on which the second reflector is produced;
c) providing a third semiconductor substrate, and epitaxial growing the active region with the quantum well structure on the third semiconductor substrate;
d) connecting the first reflector to the active region;
e) removing the third semiconductor substrate;
f) connecting the second reflector to the active region;
g) removing the second semiconductor substrate; and
prior to step f), producing an orientation mark on a surface of an outer face of the first semiconductor substrate facing away from the first reflector, wherein the orientation mark is configured so as to define a position of the vertical-cavity surface-emitting laser in a plane in parallel with the outer face of the first semiconductor substrate.

7. The method according to claim 6, wherein, step c) further comprises producing a tunnel junction region in series before or after the quantum well structure in the active region by epitaxial growth.

8. The method according to claim 6, wherein, in step c), the active region comprises a plurality of quantum well structures including the quantum well structure for generating light and a plurality of tunnel junction regions, wherein the plurality of quantum well structures and the plurality of tunnel junction regions are alternately epitaxially grown in series.

9. The method according to claim 6, wherein, step c) further comprises epitaxially growing a respective current distribution layer both before the growing the quantum well structure and after the growing the quantum well structures.

10. The method according to claim 9, wherein the current distribution layers are configured as etch stop layers.

11. The method according to claim 6, further comprising, before step d), structuring a surface of the first reflector.
